(19) United States
(12) Patent Application Publication
(10) Pub. No.: US 2013/0307579 A1
(43) Pub. Date: Nov. 21, 2013

(54) TEST SYSTEM AND LOGIC SIGNAL VOLTAGE LEVEL CONVERSION DEVICE

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: JIN-BO WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,255

(22) Filed: Dec. 24, 2012

(30) Foreign Application Priority Data
May 15, 2012 (CN) 201210149660.7

(51) Int. Cl. H03K 19/003

(52) U.S. Cl. CPC H03K 19/003
USPC 326/16

(57) ABSTRACT

A test system includes a logic signal voltage level conversion device, a first integrated circuit board, a second integrated circuit board, and a test device. The logic signal voltage level conversion device is connected to the first integrated circuit board, the second integrated circuit board, and the test device. When the first integrated circuit board is tested, the logic signal voltage level conversion device converts voltage levels of logic signals transmitted between the first integrated circuit board and the test device, to enable the first integrated circuit board to communicate with the test device. When the second integrated circuit board is tested, the logic signal voltage level conversion device converts voltage levels of logic signals transmitted between the second integrated circuit board and the test device, to enable the second integrated circuit board to communicate with the test device.

### BACKGROUND

1. Technical Field

The present disclosure relates to a test system.

2. Description of Related Art

When using terminal software, such as hyper terminal, of a first electronic device, to access an embedded system of an integrated circuit board, such as a baseboard management controller, of a second electronic device, to test the integrated circuit board, the integrated circuit board is connected to a serial interface of the first electronic device. However, a logic signal voltage level transmitted through the serial interface may be different from a logic signal voltage level of the integrated circuit board, and a signal voltage level converter is employed to convert voltage levels of the logic signal transmitted between the serial interface and the integrated circuit board. Further, voltage levels of logic signals of different kinds of integrated circuit boards are different, and a number of signal voltage level converters are needed to test the integrated circuit boards, which waste resources.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a block diagram of a test system in accordance with an embodiment of the present disclosure, wherein the test system includes a logic signal voltage level conversion device.

FIG. 2 is a circuit diagram of the logic signal voltage level conversion device of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references can mean “at least one”.

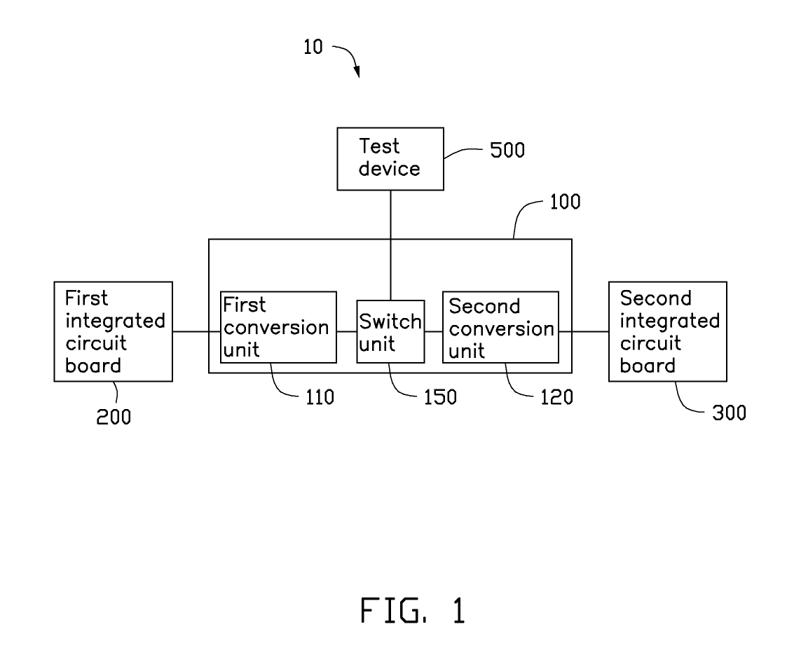

FIG. 1 shows an embodiment of a test system 10. The test system 10 includes a logic signal voltage level conversion device 100, a first integrated circuit board 200, a second integrated circuit board 300, and a test device 500. The logic signal voltage level conversion device 100 includes a first conversion unit 110, a second conversion unit 120, and a switch unit 150. The first conversion unit 110 is connected to the first integrated circuit board 200. The second conversion unit 120 is connected to the second integrated circuit board 300. The switch unit 150 is connected to the first conversion unit 110, the second conversion unit 120, and the test device 500.

When the first integrated circuit board 200 is tested by the test device 500, the switch unit 150 enables the test device 500 to communicate with the first conversion unit 110, the first conversion unit 110 converts voltage levels of logic signals transmitted between the first integrated circuit board 200 and the test device 500, to enable the first integrated circuit board 200 to communicate with the test device 500. When the second integrated circuit board 300 is tested by the test device 500, the switch unit 150 enables the test device 500 to communicate with the second conversion unit 120, the second conversion unit 120 converts voltage levels of logic signals transmitted between the second integrated circuit board 300 and the test device 500, to enable the second integrated circuit board 300 to communicate with the test device 500. In one embodiment, the first integrated circuit board 200 is a baseboard management controller, the second integrated circuit board 300 is a redundant array of independent disk card, and the test device 500 is a computer.

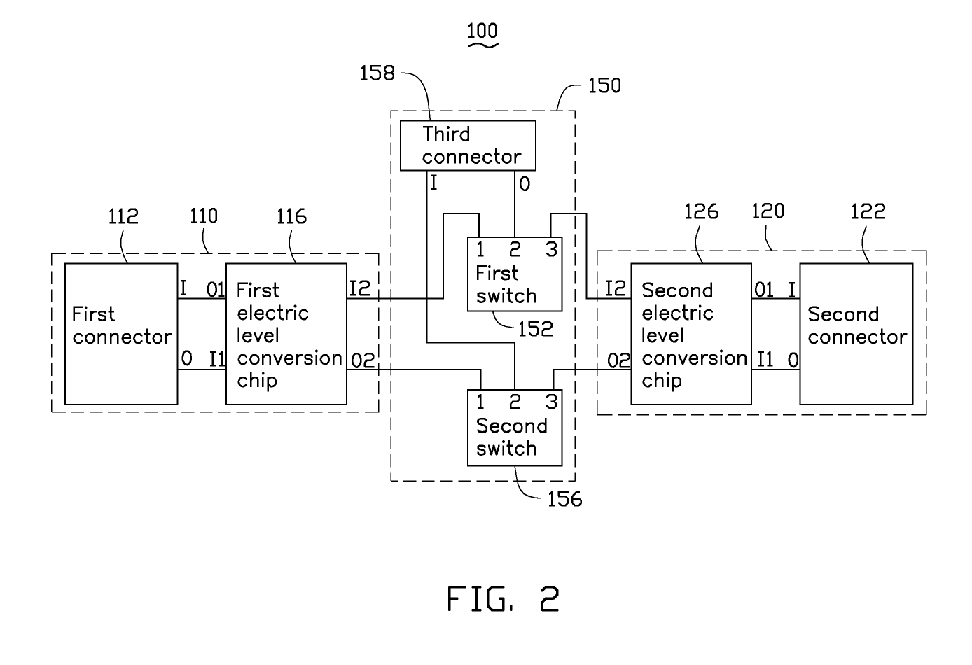

FIG. 2 shows the logic signal voltage level conversion device 100 of the embodiment. The first conversion unit 110 includes a first connector 112 and a first voltage level conversion chip 116. The second conversion unit 120 includes a second connector 122 and a second voltage level conversion chip 126. The switch unit 150 includes a first switch 152, a second switch 156, and a third connector 158. Each of the first connector 112, the second connector 122, and the third connector 158 includes an input pin I and an output pin O. Each of the first voltage level conversion chip 116 and the second voltage level conversion chip 126 includes a first input pin I1, a second input pin I2, a first output pin O1, and a second output pin O2. Each of the first switch 152 and the second switch 156 includes a first pin 1, a second pin 2, and a third pin 3.

The input pin I of the first connector 112 is connected to the first output pin O1 of the first voltage level conversion chip 116. The output pin O of the first connector 112 is connected to the first input pin I1 of the first voltage level conversion chip 116. The second input pin I2 of the first voltage level conversion chip 116 is connected to the first pin 1 of the first switch 152. The second output pin O2 of the first voltage level conversion chip 116 is connected to the first pin 1 of the second switch 156. The input pin I of the second connector 122 is connected to the first output pin O1 of the second voltage level conversion chip 126. The output pin O of the second connector 122 is connected to the first input pin I1 of the second voltage level conversion chip 126. The second input pin I2 of the second voltage level conversion chip 126 is connected to the third pin 3 of the first switch 152. The second output pin O2 of the second voltage level conversion chip 126 is connected to the third pin 3 of the second switch 156. The output pin O of the third connector 158 is connected to the second pin 2 of the first switch 152. The input pin I of the third connector 158 is connected to the second pin 2 of the second switch 156.

In one embodiment, each of the first connector 112 and the second connector 122 is a universal asynchronous receiver and transmitter. Each of the first switch 152 and the second switch 156 may be a jumper or a dip switch. The third connector 158 is a serial interface connector.

In testing of the first integrated circuit board 200, the first connector 112 is connected to a corresponding connector of the first integrated circuit board 200. The third connector 158 is connected to a corresponding connector of the test device 500. The first pin 1 of the first switch 152 is connected to the second pin 2 of the first switch 152. The first pin 1 of the second switch 156 is connected to the second pin 2 of the second switch 156. A first logic signal outputted from the test device 500 is transmitted to the second input pin I2 of the first voltage level conversion chip 116 through the third connector 158 and the first switch 152 in that order. The first voltage level conversion chip 116 converts voltage level of the first logic signal, to enable the first logic signal to be identified by the first integrated circuit board 200, and outputs the converted first logic signal to the first integrated circuit board 200 through the first output pin O1 of the first voltage level conversion chip 116 and the first connector 112 in that order. A second logic signal outputted from the first integrated circuit board 200 is transmitted to the first input pin I1 of the first voltage level conversion chip 116 through the first connector 112. The first voltage level conversion chip 116 converts voltage level of the second logic signal, to enable the second logic signal to be identified by the test device 500, and outputs the converted second logic signal to the test device 500 though the second output pin O2 of the first voltage level conversion chip 116, the second switch 156, and the third connector 158 in that order. Therefore, the test device 500 can communicate with the first integrated circuit board 200, to test the first integrated circuit board 200.

In one embodiment, a voltage level of logic “1” of a logic signal that can be identified by the test device 500 is in a range from 3 volts (V) to 12V. A voltage level of logic “0” of a logic signal that can be identified by the test device 500 is in a range from −3V to −12V. A voltage level of logic “1” of a logic signal that can be identified by the first integrated circuit board 200 is 3.3V. A voltage level of logic “0” of a logic signal that can be identified by the first integrated circuit board 200 is 0V. The first voltage level conversion chip 116 converts the voltage level of logic “1” of the first logic signal into 3.3V, and converts the logic “0” of the first logic signal into 0V, to enable the first logic signal to be identified by the first integrated circuit board 200. The first voltage level conversion chip 116 converts the voltage level of logic “1” of the second logic signal into an voltage level in the range from 3V to 12V, and converts the logic “0” of the second logic signal into an voltage level in the range from −3V to −12V, to enable the second logic signal to be identified by the test device 500.

In testing of the second integrated circuit board 300, the second connector 122 is connected to a corresponding connector of the second integrated circuit board 300. The third connector 158 is connected to the corresponding connector of the test device 500. The second pin 2 of the first switch 152 is connected to the third pin 3 of the first switch 152. The second pin 2 of the second switch 156 is connected to the third pin 3 of the second switch 156. A third logic signal outputted from the test device 500 is transmitted to the second input pin I2 of the second voltage level conversion chip 126 through the third connector 158 and the first switch 152 in that order. The second voltage level conversion chip 116 converts voltage level of the third logic signal, to enable the third logic signal to be identified by the second integrated circuit board 300, and outputs the converted third logic signal to the second integrated circuit board 300 through the first output pin O1 of the second voltage level conversion chip 126 and the second connector 122 in that order. A fourth logic signal outputted from the second integrated circuit board 300 is transmitted to the first input pin I1 of the second voltage level conversion chip 126 through the second connector 122. The second voltage level conversion chip 126 converts voltage level of the fourth logic signal, to enable the fourth logic signal to be identified by the test device 500, and outputs the converted fourth logic signal to the test device 500 though the second output pin O2 of the second voltage level conversion chip 126, the second switch 156, and the third connector 158 in that order. Therefore, the test device 500 can communicate with the second integrated circuit board 300, to test the second integrated circuit board 300.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A logic signal voltage level conversion device, to convert voltage levels of logic signals transmitted between a first integrated circuit board and a test device, and convert voltage levels of logic signals transmitted between a second integrated circuit board and the test device, the logic signal voltage level conversion device comprising:
a first conversion unit connected to the first integrated circuit board;
a second conversion unit connected to the second integrated circuit board; and
a switch unit connected to the first conversion unit, the second conversion unit, and the test device;
wherein the switch unit enables the test device to communicate with the first conversion unit in response to the first integrated circuit board being tested, and enables the test device to communicate with the second conversion unit in response to the second integrated circuit board being tested;
wherein the first conversion unit converts voltage level of a first logic signal outputted from the test device to enable the first logic signal to be identified by the first integrated circuit board, and converts voltage level of a second logic signal outputted from the first integrated circuit board to enable the second logic signal to be identified by the test device; and
wherein the second conversion unit converts voltage level of a third logic signal outputted from the test device to enable the third logic signal to be identified by the second integrated circuit board, and converts voltage level of a fourth logic signal outputted from the second integrated circuit board to enable the fourth logic signal to be identified by the test device.

2. The logic signal voltage level conversion device of claim 1, wherein the first conversion unit comprises:
a first connector comprising an input pin and an output pin; and
a first voltage level conversion chip comprising a first input pin connected to the output pin of the first connector, a first output pin connected to the input pin of the first connector, a second input pin, and a second output pin.

3. The logic signal voltage level conversion device of claim 2, wherein the second conversion unit comprises:
a second connector comprising an input pin and an output pin; and
a second voltage level conversion chip comprising a first input pin connected to the output pin of the second connector, a first output pin connected to the input pin of the second connector, a second input pin, and a second output pin.

4. The logic signal voltage level conversion device of claim 3, wherein the switch unit comprises:
a third connector comprising an input pin and an output pin;
a first switch comprising a first pin connected to the second input pin of the first voltage level conversion chip, a second pin connected to the output pin of the third connector, and a third pin connected to the second input pin of the second voltage level conversion chip; and
a second switch comprising a first pin connected to the second output pin of the first voltage level conversion chip, a second pin connected to the input pin of the third connector, and a third pin connected to the second output pin of the second voltage level conversion chip.

5. The logic signal voltage level conversion device of claim 4, wherein the first connector is connected to the first integrated circuit board, the third connector is connected to the test device, the first pin of the first switch is connected to the second pin of the first switch, and the first pin of the second switch is connected to the second pin of the second switch, in response to the first integrated circuit board being tested;
the first logic signal outputted from the test device is transmitted to the second input pin of the first voltage level conversion chip through the third connector and the first switch in that order, the first voltage level conversion chip converts voltage level of the first logic signal, to enable the first logic signal to be identified by the first integrated circuit board, and outputs the converted first logic signal to the first integrated circuit board through the first output pin of the first voltage level conversion chip and the first connector in that order; and
the second logic signal outputted from the first integrated circuit board is transmitted to the first input pin of the first voltage level conversion chip through the first connector, the first voltage level conversion chip converts voltage level of the second logic signal, to enable the second logic signal to be identified by the test device, and outputs the converted second logic signal to the test device though the second output pin of the first voltage level conversion chip, the second switch, and the third connector in that order.

6. The logic signal voltage level conversion device of claim 4, wherein the second connector is connected to the second integrated circuit board, the third connector is connected to the test device, the second pin of the first switch is connected to the third pin of the first switch, and the second pin of the second switch is connected to the third pin of the second switch, in response to the second integrated circuit board being tested;
the third logic signal outputted from the test device is transmitted to the second input pin of the second voltage level conversion chip through the third connector and the first switch in that order, the second voltage level conversion chip converts voltage level of the third logic signal, to enable the third logic signal to be identified by the second integrated circuit board, and outputs the converted third logic signal to the second integrated circuit board through the first output pin of the second voltage level conversion chip and the second connector in that order; and
the fourth logic signal outputted from the second integrated circuit board is transmitted to the first input pin of the second voltage level conversion chip through the second connector, the second voltage level conversion chip converts voltage level of the fourth logic signal, to enable the fourth logic signal to be identified by the test device, and outputs the converted fourth logic signal to the test device though the second output pin of the second voltage level conversion chip, the second switch, and the third connector in that order.

7. The logic signal voltage level conversion device of claim 4, wherein each of the first connector and the second connector is a universal asynchronous receiver and transmitter, and the third connector is a serial interface connector.

8. The logic signal voltage level conversion device of claim 4, wherein each of the first switch and the second switch is a jumper.

9. The logic signal voltage level conversion device of claim 4, wherein each of the first switch and the second switch is a dip switch.

10. A test system comprising:
a first integrated circuit board and a second integrated circuit board;
a test device to test the first integrated circuit board and the second integrated circuit board; and
a logic signal voltage level conversion device comprising:
a first conversion unit connected to the first integrated circuit board;
a second conversion unit connected to the second integrated circuit board; and
a switch unit connected to the first conversion unit, the second conversion unit, and the test device;
wherein the switch unit enables the test device to communicate with the first conversion unit in response to the first integrated circuit board being tested, and enables the test device to communicate with the second conversion unit in response to the second integrated circuit board being tested;
wherein the first conversion unit converts voltage level of a first logic signal outputted from the test device to enable the first logic signal to be identified by the first integrated circuit board, and converts voltage level of a second logic signal outputted from the first integrated circuit board to enable the second logic signal to be identified by the test device; and
wherein the second conversion unit converts voltage level of a third logic signal outputted from the test device to enable the third logic signal to be identified by the second integrated circuit board, and converts voltage level of a fourth logic signal outputted from the second integrated circuit board to enable the fourth logic signal to be identified by the test device.

11. The test system of claim 10, wherein the first conversion unit comprises:
a first connector comprising an input pin and an output pin; and
a first voltage level conversion chip comprising a first input pin connected to the output pin of the first connector, a first output pin connected to the input pin of the first connector, a second input pin, and a second output pin.

12. The test system of claim 11, wherein the second conversion unit comprises:
a second connector comprising an input pin and an output pin; and
a second voltage level conversion chip comprising a first input pin connected to the output pin of the second connector, a first output pin connected to the input pin of the second connector, a second input pin, and a second output pin.

13. The test system of claim 12, wherein the switch unit comprises:
a third connector comprising an input pin and an output pin;
a first switch comprising a first pin connected to the second input pin of the first voltage level conversion chip, a second pin connected to the output pin of the third connector, and a third pin connected to the second input pin of the second voltage level conversion chip; and
a second switch comprising a first pin connected to the second output pin of the first voltage level conversion chip, a second pin connected to the input pin of the third connector, and a third pin connected to the second output pin of the second voltage level conversion chip.

14. The test system of claim 13, wherein the first connector is connected to the first integrated circuit board, the third connector is connected to the test device, the first pin of the first switch is connected to the second pin of the first switch, and the first pin of the second switch is connected to the second pin of the second switch, in response to the first integrated circuit board being tested;
the first logic signal outputted from the test device is transmitted to the second input pin of the first voltage level conversion chip through the third connector and the first switch in that order, the first voltage level conversion chip converts voltage level of the first logic signal, to enable the first logic signal to be identified by the first integrated circuit board, and outputs the converted first logic signal to the first integrated circuit board through the first output pin of the first voltage level conversion chip and the first connector in that order; and
the second logic signal outputted from the first integrated circuit board is transmitted to the first input pin of the first voltage level conversion chip through the first connector, the first voltage level conversion chip converts voltage level of the second logic signal, to enable the second logic signal to be identified by the test device, and outputs the converted second logic signal to the test device though the second output pin of the first voltage level conversion chip, the second switch, and the third connector in that order.

15. The test system of claim 13, wherein the second connector is connected to the second integrated circuit board, the third connector is connected to the test device, the second pin of the first switch is connected to the third pin of the first switch, and the second pin of the second switch is connected to the third pin of the second switch, in response to the second integrated circuit board being tested;
the third logic signal outputted from the test device is transmitted to the second input pin of the second voltage level conversion chip through the third connector and the first switch in that order, the second voltage level conversion chip converts voltage level of the third logic signal, to enable the third logic signal to be identified by the second integrated circuit board, and outputs the converted third logic signal to the second integrated circuit board through the first output pin of the second voltage level conversion chip and the second connector in that order; and
the fourth logic signal outputted from the second integrated circuit board is transmitted to the first input pin of the second voltage level conversion chip through the second connector, the second voltage level conversion chip converts voltage level of the fourth logic signal, to enable the fourth logic signal to be identified by the test device, and outputs the converted fourth logic signal to the test device though the second output pin of the second voltage level conversion chip, the second switch, and the third connector in that order.

16. The test system of claim 13, wherein each of the first connector and the second connector is a universal asynchronous receiver and transmitter, and the third connector is a serial interface connector.

17. The test system of claim 13, wherein each of the first switch and the second switch is a jumper.

18. The test system of claim 13, wherein each of the first switch and the second switch is a dip switch.

19. The test system of claim 10, wherein the first integrated circuit board is a baseboard management controller, and the second integrated circuit board is a redundant array of independent disk card.
